(19) United States
(12) Patent Application Publication
(10) Pub. No.: US 2025/0311160 A1
(43) Pub. Date: Oct. 2, 2025

(54) HEAT PIPE COOLING

(71) Applicant: Adeia Semiconductor Technologies LLC, San Jose, CA (US)

(72) Inventors: Belgacem Haba, Saratoga, CA (US); Rajesh Katkar, Milpitas, CA (US)

(21) Appl. No.: 18/674,659

(22) Filed: May 24, 2024

Related U.S. Application Data
(60) Provisional application No. 63/571,907, filed on Mar. 29, 2024.

(51) Int. Cl. H05K 7/20; F28D 15/02; F28D 15/04

(52) U.S. Cl. CPC H05K 7/20336; F28D 15/0275; F28D 15/046

(57) ABSTRACT

Embodiments herein provide for an integrated cooling assembly comprising a semiconductor device and a heat pipe attached to a backside of the semiconductor device. The heat pipe comprises a shell which defines a heat pipe chamber, the heat pipe shell having an inner surface and an outer surface, the inner surface of the heat pipe chamber includes a wick material, and the backside of the semiconductor device is in contact with the wick material.

### CROSS-REFERENCE TO RELATED APPLICATION

This application claims the benefit of U.S. Provisional Patent Application No. 63/571,907, filed Mar. 29, 2024, which is incorporated by reference herein in its entirety.

### FIELD

The present disclosure relates to cooling for microelectronic devices, and in particular, embedded cooling systems and configurations thereof for device packages and methods of manufacturing the same.

### BACKGROUND

Energy consumption poses a critical challenge for the future of large-scale computing as the world's computing energy requirements are rising at a rate that most would consider unsustainable. Some models predict that the information, communication and technology (ICT) ecosystem could exceed 20% of global electricity use by 2030, with direct electrical consumption by large-scale computing centers accounting for more than one-third of that energy usage. A significant portion of the energy used by such large-scale computing centers is devoted to cooling since even small increases in operating temperatures can negatively impact the performance of microprocessors, memory devices, and other electronic components. While some of this energy is expended to operate the cooling systems that are directly cooling the chips (e.g. heat spreaders, heat pipes, etc.), energy consumption/costs for indirect cooling can also be quite staggering. Indirect cooling energy costs include, for example, cooling or air conditioning of data center buildings. Data center buildings can house thousands, to tens of thousands or more, of high performance chips in server racks and each of those high performance chips is a heat source. An uncontrolled ambient temperature in a data center will adversely affect the performance of the individual chips and the data center system performance as a whole.

Thermal dissipation in high-power density chips (semiconductor devices/die) is also a critical challenge as improvements in chip performance, e.g., through increased gate or transistor density due to advanced processing nodes, evolution of multi-core microprocessors, etc. have resulted in increased power density and a corresponding increase in thermal flux that contributes to elevated chip temperatures. Higher density of transistors also increases the length of metal wiring on the chips, which generates its own additional thermal flux due to Joule heating of these wires due to higher currents. These elevated temperatures are undesirable as they can degrade the chip's operating performance, efficiency, reliability, and remaining life. Cooling systems used to maintain the chip at a desired operating temperature typically remove heat using one or more heat dissipation devices, e.g., thermal spreaders, heat pipes, cold plates, liquid cooled heat pipe systems, thermal-electric coolers, heat sinks, etc. One or more thermal interface material(s), such as, for example, thermal paste, thermal adhesive, or thermal gap filler, may be used to facilitate heat transfer between the surfaces of a chip and heat dissipation device(s). A thermal interface material(s) (TIM(s)) is any material that is inserted between two components to enhance the thermal coupling therebetween. Unfortunately, the combined thermal resistance of (i) the thermal resistance of interfacial boundary regions between a TIM(s) and the chip and/or the heat dissipation device(s); and (ii) the thermal resistance of a thermal interface material(s) itself can inhibit heat transfer from the chip to the heat dissipation devices, undesirably reducing the cooling efficiency of the cooling system.

Generally speaking, there are multiple components between the heat dissipating sources (i.e., active circuitry) in the chips and the heat dissipation devices, each of which contribute to the system thermal resistance accumulatively along the heat transfer paths and raise chip junction temperatures from the ambient.

Such cooling systems can suffer from reduced cooling efficiency due to the design and manufacture of system components. Some devices, for various reasons, cannot employ active cooling, and thus the passive heat dissipation from such devices provides an upper limit of device processing power and device heat and power dissipation. In an effort to reduce the operating temperature of such devices, whilst enabling an increase in processing power thereof, it is desirable to increase the heat dissipation envelope. Accordingly, heat may be dissipated from such devices by improving the heat transfer characteristics of a passive cooling arrangement.

Accordingly, there exists a need in the art for improved energy-efficient cooling systems, by reducing system thermal resistance, and methods of manufacturing the same.

### SUMMARY

Embodiments herein provide cooling assemblies attached to advanced device packages. Advantageously, the integrated device cooling assemblies deliver appropriate cooling directly to a semiconductor device so as to obtain effective cooling of the device.

A first general aspect includes an integrated cooling assembly comprising a semiconductor device and a heat pipe attached to a backside of the semiconductor device. The heat pipe comprises a shell which defines a heat pipe chamber, the heat pipe shell having an inner surface and an outer surface, the inner surface of the heat pipe chamber includes a wick material, and the backside of the device is in contact with the wick material.

Implementations of the cooling assembly according to the first general aspect may include one or more of the following features. In some embodiments, the backside of the device may form a portion of the shell of the heat pipe such that the backside of the device forms a portion of the inner surface of the heat pipe chamber. The heat pipe is attached to the backside of the semiconductor device with adhesive. In some embodiments the adhesive is a compliant adhesive. In some embodiments the heat pipe is attached to the backside of the semiconductor device with solder. In some embodiments the outer surface of the heat pipe includes a dielectric layer deposited thereupon. In some embodiments the dielectric layer is be disposed between the outer surface of the heat pipe and the backside of die, and the heat pipe may be attached to the backside of the die using direct dielectric bonds formed between the dielectric layer and the backside of the semiconductor device. In some embodiments, the wicking material is a mesh. In some embodiments, the wicking material is a sintered powder deposited on the inner surface of the heat pipe chamber. In some embodiments, the wicking material is a braid or mesh.

A second general aspect includes a method of manufacturing an integrated cooling assembly. The method comprises providing a semiconductor device having a backside, providing a heat pipe, and applying a wicking material to a portion of the backside of the semiconductor device. The method further comprises attaching the heat pipe to the backside of the semiconductor device such that the portion of the backside of the device forms part of an outer wall of the heat pipe and the wicking material on the portion of the backside of the semiconductor device lies within an internal chamber of the heat pipe, evacuating the inside of the heat pipe chamber chamber of the heat pipe such that the heat pipe chamber chamber of the heat pipe is under at least partial vacuum conditions, introducing a working fluid into the internal heat pipe chamber of the heat pipe, and sealing the heat pipe chamber of the heat pipe.

A third general aspect includes a method of manufacturing an integrated cooling assembly. The method comprises providing a semiconductor device and a heat pipe, applying compliant adhesive to a perimeter of the backside of the semiconductor device, and placing wicking material within a boundary of the compliant adhesive and in contact with the backside of the semiconductor device. The method further comprises attaching the heat pipe to the compliant adhesive on the backside of the semiconductor device, at least partially evacuating the interior of the heat pipe to form a vacuum therein and introducing liquid into the heat pipe, and sealing the heat pipe.

### BRIEF DESCRIPTION OF THE DRAWINGS

The above and other objects and advantages of the disclosure will be apparent upon consideration of the following detailed description, taken in conjunction with the accompanying drawings, in which:

FIG. 1A illustrates a device package with an external heat sink;

FIG. 1B is a schematic view of a cooling arrangement which includes a heat pipe;

FIG. 2 is a schematic view of a cooling arrangement which includes a heat pipe cooler;

FIG. 3A is a schematic view of a cooling arrangement which includes a heat pipe in accordance with embodiments described herein;

FIG. 3B is a schematic view of a wicking material for use in cooling arrangements described herein;

FIG. 3C is a schematic view of a heat pipe in accordance with embodiments described herein;

FIG. 4A is a schematic view of a partially-assembled cooling arrangement which includes a heat pipe in accordance with embodiments described herein;

FIG. 4B is a schematic view of a further cooling arrangement which includes a heat pipe in accordance with embodiments described herein;

FIG. 5 is a schematic view of another cooling arrangement which includes a heat pipe in accordance with embodiments described herein;

FIG. 6 is a schematic view of a device which includes a cooling arrangement having a heat pipe as described herein;

FIG. 7 is a schematic view of a cooling arrangement which includes a heat pipe as described herein in combination with a heat sink;

FIG. 8 shows an exemplary method for manufacture of a cooling arrangement in accordance with embodiments described herein; and

FIG. 9 shows a further exemplary method for manufacture of a cooling arrangement in accordance with embodiments described herein.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed or mounted. The term substrate also includes “semiconductor substrates” that provide a supporting material upon which elements of a semiconductor device are fabricated or attached, and any material layers, features, and/or electronic devices formed thereon, therein, or therethrough. Examples of substrate material that may be used in applications that generate high thermal density include, but are not limited to, Si, GaN, SiC, InP, GaP, InGaN, AlGaInP, AlGaAs, etc.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,” “top,” “bottom” and the like are generally made with reference to the X, Y, and Z directions set forth by X, Y and Z axis in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements. Furthermore, the term “horizontal” is generally made with reference to the X-axis direction and the Y-axis direction set forth in the drawings. The term “vertical” is generally made with reference to the Z-axis direction set forth in the drawings.

Various embodiments disclosed herein include bonded structures in which two or more elements are directly bonded to one another without an intervening adhesive (referred to herein as “direct bonding”, or “directly bonded”). In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. As discussed in more detail below, the process of direct bonding provides a reduction of thermal resistance between a semiconductor device and a cold plate. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (1^{st}) nonconductive feature directly bonded to another (2^{nd}) nonconductive feature, and ii) at least one (1^{st}) conductive feature directly bonded to another (2^{nd}) conductive feature, without any intervening adhesive. In some hybrid bonding embodiments, there are many 1^{st} conductive features, each directly bonded to a 2^{nd} conductive feature, without any intervening adhesive. In some embodiments, nonconductive features on the first element are directly bond to nonconductive features of the second element at room temperature without any intervening adhesive, which is followed by bonding of conductive features of the first element directly bonded to conductive features of the second element at via annealing at slightly higher temperatures (e.g., >100° C., >200° C., >250° C., >300° C., etc.).

Unless otherwise noted, the terms “cooling assembly” and “integrated cooling assembly” generally refers to a semiconductor device and a cooler such as a heat pipe or cold plate attached to the semiconductor device. The cooler may be attached to the semiconductor device by use of a compliant adhesive layer or by direct dielectric or hybrid bonding. For example, the cooler may include material layers and or metal features which facilitate direct dielectric or hybrid bonding with the semiconductor device. Beneficially, the backside of the semiconductor device is directly exposed to the cooler, thus providing for direct heat transfer therebetween. Unless otherwise noted, the integrated cooling assemblies described herein may be used with any desired fluid, e.g., liquid, gas, and/or vapor-phase coolants, such as water and/or glycol, for example. In some embodiments, the coolant fluid(s) may contain additives to enhance the conductivity of the cooling fluid(s) within the integrated cooling assemblies. The additives may comprise for example, nano-particles of carbon nanotubes, nano-particles of graphene, and/or nano-particles of metal oxides. The concentration of these nano-particles may be less than 1%, less than 0.2%, or less than 0.05%. The cooling fluids may also contain small amount of glycol or glycols (e.g., propylene glycol, ethylene glycol, etc.) to reduce frictional shear stress and drag coefficient in the cooling fluid(s) within the integrated cooling assembly.

As described below, a cooler which is formed of a heat pipe or heat pipes may be used to control the temperature of semiconductor devices. The fluid within the heat pipe or heat pipes absorbs heat and conducts heat away from the semiconductor device.

This disclosure describes embodiments involving the architecture of system and component elements that can be employed to provide for the cooling of semi-conductor components, packaging, and boards. However, those skilled in the art will appreciate the disclosed components and arrangements can be deployed and used in scenarios where component heat up or thermal warm up is desired for a component that is currently outside the low end of the desired operational range. Components that are outside the low end of their operational range can, if started in a cold environment, experience thermal warping or cracking up to and including thermal overexpansion and contact separation that may impair the successful operation of the system. Therefore, in these scenarios, the architectures and embodiments disclosed herein can be used where the indirect thermal solutions supporting them are repurposed or operated in a hybrid configuration to provide warming fluids or heat transfer media to accomplish the warm-up or heat-up scenario. These scenarios are controlled by systems not shown here to bring temperatures up at a speed or timing that enables the materials to avoid the excessive thermal expansion or unequal thermal expansion that may occur among the materials of the semiconductor or packaging being serviced by the thermal solution. Once the component or packaging is brought up into the normal operating range, it can be safely started and brought to a useful operational state.

Considering the warm-up or heat-up embodiments introduced above, the balance of this disclosure and terms used should be viewed in a light that also considers the design option for such warm-up or heat-up. Thus, where terms such as cooling channel, cooling chamber volume, and cooling port are used, for example, such terms could also be considered as a thermal control channel, a thermal control volume, or a thermal control port, respectively. A person of skill would understand that heat flux or heat transfer would go in a different direction, but the design concepts are similar and can be successfully employed in the various embodiments.

A heat pipe or heat pipe cooler is a heat-transfer device that employs phase transition to transfer heat energy. At the hot interface of a heat pipe, that is to say the portion of the heat pipe which is in contact with a heat source, a volatile liquid in contact with a thermally conductive solid surface turns into a vapor by absorbing heat from that surface. The vapor then travels along the heat pipe to the cold interface. The cold interface may for example be a heat sink, or the wall or casing or a cooling fan of a device such as a mobile device, computing device, a handheld device, or other similar devices. At the cold interface, the vapor condenses back into a liquid, releasing the latent heat. The liquid then returns to the hot interface through capillary action, wicking effect, centrifugal force, or gravity and the cycle repeats.

Because of the high heat transfer coefficients involved in boiling and condensation, heat pipes are effective thermal conductors. The effective thermal conductivity may vary with the length of a heat pipe, and can approach 100 kW/(m·K) for long heat pipes, in comparison with approximately 0.4 kW/(m·K) for heat transfer using plain copper alone. Heat pipes are generally made of hollow copper pipes and employ water as a working fluid. A working fluid of a heat pipe is captive within the heat pipe and vaporization and subsequent condensation of the working fluid affects the cooling effect provided by the heat pipe. Use of heat pipes is common in consumer electronic devices such as mobiles, desktops, laptops, tablets, smartphones, etc.

A typical heat pipe generally consists of a sealed pipe or tube made of a material that is compatible with the working fluid, such as copper for water heat pipes, or aluminum for ammonia heat pipes. The working fluid could be water, distilled water, water mixed with a surfactant, and/or water mixed with another fluid for improved viscosity management. Typically, a vacuum pump is used to evacuate the interior of the heat pipe to remove the air from the empty heat pipe. The heat pipe is generally partially filled with a working fluid and then sealed. The working fluid mass is chosen so that the heat pipe contains both vapor and liquid over the operating temperature range. In the case of heat pipes to be used with a consumer electronics device, the heat pipe may be formed of copper and employ water as the working fluid. Heat pipes typically contain no mechanical moving parts and therefore require minimal maintenance. Heat pipes generally include an outer wall which forms the heat pipe shell, a wick, and a working fluid. Efficient wicking material should have good thermal conductivity to transport from heat source to cooling liquid; support the capillary action to transfer the condensed liquid back to the heat source; and the capability to resist the high temperatures involved. Few examples of the wicking media can include homogenous wicking media such as metal fibers (e.g., made out of metals such as copper, aluminum, nickel, stainless steel, titanium, metal alloys, etc.), porous metals (e.g., porous copper), wire meshes (e.g., core wires), fibrous or dendritic materials, glass fibers, woven cloths or other composite wicking media. Heat pipes are designed for very long term operation with minimal maintenance, so the heat pipe shell and wick are preferably compatible with the working fluid.

Heat pipes containing graphene may improve cooling performance in electronics.

A heat pipe employs phase change to transfer thermal energy from one point to another by the vaporization and condensation of a working fluid or coolant. Heat pipes rely on a temperature difference between the ends of the pipe, and cannot lower temperatures at either end below the ambient temperature (hence they tend to equalize the temperature within the pipe). Generally speaking, when one end of the heat pipe is heated, the working fluid inside the pipe at that end vaporizes and increases the vapor pressure inside the cavity of the heat pipe. The latent heat of vaporization absorbed by the working fluid reduces the temperature at the hot end of the pipe.

The vapor pressure over the hot liquid working fluid at the hot end of the pipe is higher than the equilibrium vapor pressure over the condensing working fluid at the cool end of the pipe, and this pressure difference drives a rapid mass transfer to the condensing end where the excess vapor condenses, releases its latent heat, and warms the cool end of the pipe. Non-condensing gases (caused by contamination for instance) in the vapor impede the gas flow and reduce the effectiveness of the heat pipe, particularly at low temperatures, where vapor pressures are low. The speed of molecules in a gas is approximately the speed of sound, and in the absence of noncondensing gases (i.e., if there is only a gas phase present) this is the upper limit to the velocity with which they could travel in the heat pipe. In practice, the speed of the vapor through the heat pipe is limited by the rate of condensation at the cold end and far lower than the molecular speed.

For a heat pipe to transfer heat, it typically contains saturated liquid and its vapor (the saturated liquid in gas phase). The saturated liquid vaporizes and travels within the heat pipe to the cold interface of the heat pipe, which may act as a condenser, cooling the vapor, condensing it, and turning it back to a saturated liquid. In a typical heat pipe, the condensed liquid is returned to the evaporator using a wick structure exerting a capillary action on the liquid phase of the working fluid. Wick structures used in heat pipes may include sintered metal powder, fibrous or dendritic material, wire mesh, screen, and/or grooved wicks, which have a series of grooves parallel to the pipe axis. When the condenser is located above the evaporator in a gravitational field, gravity can return the liquid. In this case, the heat pipe is a thermosiphon. Finally, rotating heat pipes use centrifugal forces to return liquid from the condenser to the evaporator.

In general, heat may be transferred into a heat pipe from a device or package which generates heat in operation, via the medium of thermal interface material (TIM) often by way of a heat spreader on the device or package. In an example of CPU cooling in a laptop computer, a heat pipe may be thermally attached to the heat spreader of a CPU package (i.e., in thermal contact therewith) within the laptop computer by way of TIM. It is to be understood that further fixing may also be employed, that is to say the heat pipe may be mechanically attached to the PCB onto which the CPU is mounted, and the device end of the heat pipe may be mounted in an attachment portion which may be made of copper or the like, which may aid the thermal contact between the CPU package and the heat pipe.

Heat may pass from the device or package (the CPU package in this case) into the heat pipe via the thermal interface material, with the operation of the heat pipe transferring the heat away from the device or package to the cool end of the heat pipe which may be affixed to a heatsink, a cooler, a fan arrangement, or other similar devices. The heatsink, cooler, or fan arrangement may then dump the heat to atmosphere, such that the heat generated by the device or package is transferred away from the device or package and to atmosphere.

As used herein, the terms “chip”, “die”, and “device package” may be used interchangeably.

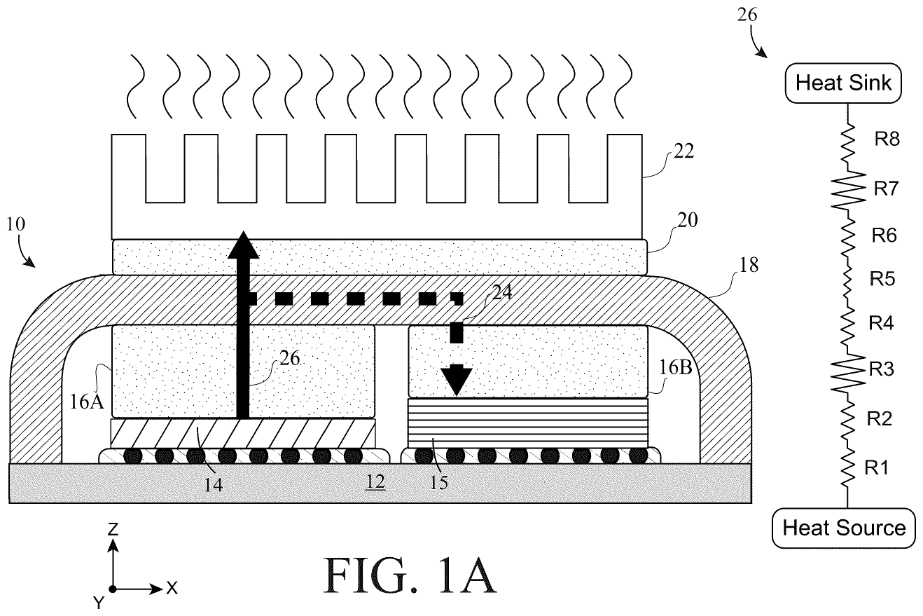

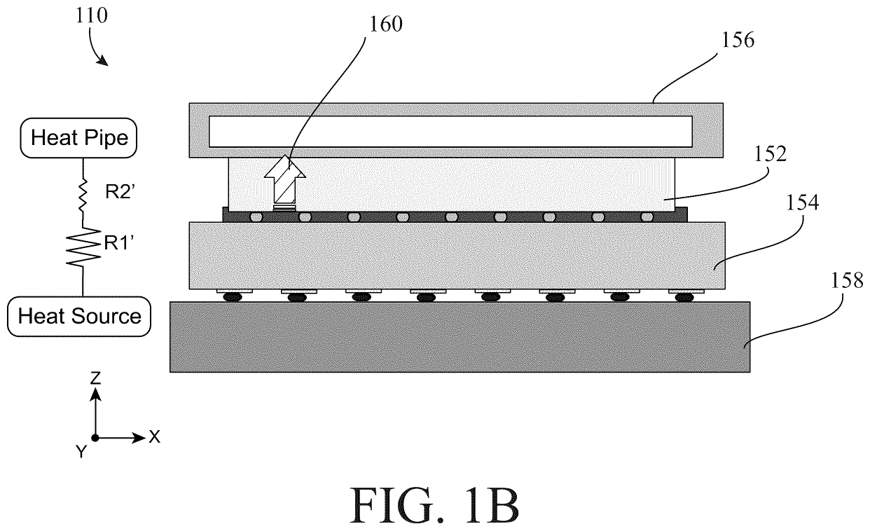

FIG. 1A is a schematic side view of a device package 10 and a heat sink 22 attached to the device package 10. The device package 10 typically includes a package substrate 12, a first device 14, a device stack 15, a heat spreader 18, and first TIM layers 16A, 16B thermally coupling the first device 14 and device stack 15 to the heat spreader 18. The device package 10 is thermally coupled to a heat sink 22 through a second TIM layer 20. The TIM layers 16A, 16B, 20 facilitate thermal contact between components in the device package 10 and between the device package 10 and the heat sink 22.

As heat flux density increases with increasing power density in advanced semiconductor devices, the cumulative thermal resistance of the system illustrated in FIG. 1A is increasingly problematic as heat cannot be dissipated quickly enough to allow semiconductor devices to run at optimal power. Consequently, the energy efficiency of semiconductor devices is reduced. Furthermore, heat is transferred between semiconductor devices within the device package 10, as shown with heat transfer path 24 (illustrated as a dashed line), where heat may be undesirable transferred from the first device 14 having a high heat flux, such as a CPU or GPU, to the device stack 15 having low heat flux, such as memory, through the heat spreader 18.

For example, as shown in FIG. 1A, each device package component and the respective interfacial boundaries therebetween has a corresponding thermal resistance which forms heat transfer path 26 (illustrated by arrow 26 in FIG. 1A). The left-hand side of FIG. 1A illustrates the heat transfer path 26 as a series of thermal resistances R1-R8 between a heat source and a heat sink. Here, R1 is the thermal resistance of the bulk semiconductor material of the first device 14. R3 and R7 are the thermal resistances of the first TIM layers 16A, 16B and the second TIM layer 20, respectively. R5 is the thermal resistance of the heat spreader 18. R2, R4, R6, and R8 represent the thermal resistance at the interfacial region of the components (e.g., contact resistances). In a typical cooling system, R3 and R7 may account for 80% or more of the cumulative thermal resistance of the heat transfer path 26 and R5 may account for 5% or more. R1 of the first device 14 and R2, R4, R6, and R8 of the interfaces account for the remaining cumulative thermal resistance. Accordingly, embodiments herein provide for integrated cooling assemblies embedded within a device package. The embedded cooling assemblies shorten the thermal resistance path between a semiconductor device and a heat sink and reduce thermal communication between semiconductor devices disposed in the same device package, such as described in relation to the figures herein.

Turning now to FIG. 1B, a device cooling arrangement 110 is shown. In FIG. 1B, a device package 152 and a package substrate 154 are shown. The package substrate 154 is attached to a main board 158 which may be a PCB. In the arrangement 110, a heat pipe 156 is attached directly to the backside of the device package 152. No heat spreader or TIM is present between the device package 152 and the heat pipe 156. In some embodiments, some portions of the heat pipe 156 is attached to the backside of the device package 152 using an adhesive. In some embodiments, the heat extraction media of the heat pipe (e.g., wicking material) is in contact with the chip.

A heat transfer path 160 is shown, which denotes heat transfer from the device package 152 into the heat pipe 156.

Between the heat source, in this case the device package 152, and the cooler, in this case a heat pipe 156, there are fewer sources of thermal resistance as compared to the arrangement shown in FIG. 1A. Here, R1′ is the thermal resistance of the bulk semiconductor material of the package substrate 154 and R2′ represents the thermal resistance at the interfacial region of the device package 152 and the heat pipe 156 (e.g., the contact resistance).

Therefore, the sources of thermal resistance shown in FIG. 1B include the thermal resistance of the chip 152 (e.g., thermal resistance between the heat generating active side at the bottom and chip surface on top) and interface thermal resistance between the chip 152 and the heat pipe 156.

These two sources of thermal resistance, R1′ and R2′, combine to give a total thermal resistance may be taken as the thermal resistance R, of the silicon of the device package 152 and the thermal resistance of the interfacial region. Therefore, the total thermal resistance, R, is R1′+R2′=R(silicon)+R(interface). That which is shown in FIG. 1A, includes thermal resistances R1-R8, and that which is shown in FIG. 1B includes thermal resistances R1′ and R2′. The sum of R1′ and R2′ has a greatly reduced thermal resistance as compared to the sum of R1-R8. Therefore, that which is shown in FIG. 1B has a significantly reduced thermal resistance as compared to that which is shown in FIG. 1A.

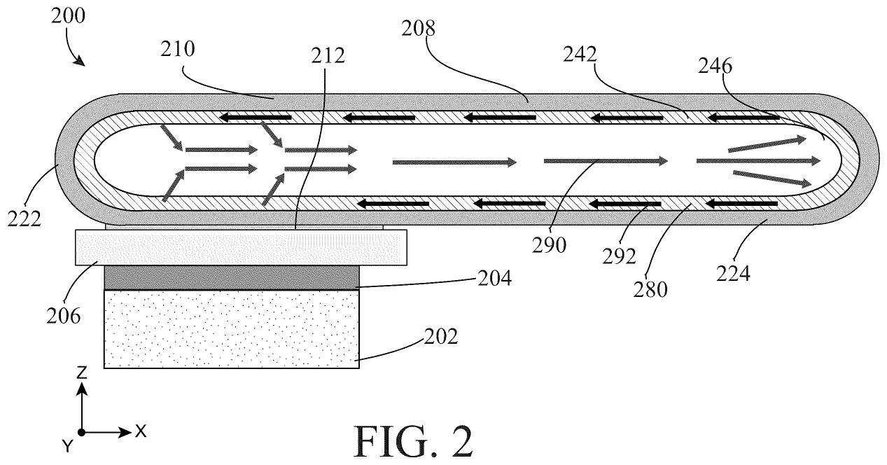

With reference now to FIG. 2, a device cooling arrangement 200 is shown. A device package or chip 202 is in thermal contact with a metal plate 206 via a layer of TIM 204. The metal plate 206 may be the base of a heat pipe cooler 208, similar to the heat pipe coolers described above. The shape and size (or footprint) of the metal plate 206 is designed so as to match the shape and size/footprint of the device package (or chip) 202. The heat pipe cooler 208 is constructed such that the heat pipe 210 itself is affixed to, and in thermal contact with, the metal plate 206 via a layer of solder 212. It is, however, to be understood that any other suitable affixing method may be employed, for example by using brazing, TIM or adhesive. Heat is transferred from the device package 202 to the heat pipe 210 via the layer of TIM 204, the metal plate 206, and the layer of solder 212. This heat transfer path may affect cooling of the device package 202, with heat transferred from a device end 222 of the heat pipe 210, which may be the end of the heat pipe 210 which is closest to the device package 202, toward a distal end 224 of the heat pipe 210. Heat may then be subsequently transferred away from the distal end 224 of the heat pipe 210 in order to cool the device package 202 by attaching the distal end to the cooling mechanism like a fan, a heat sink, a radiator, etc.

As described in connection with FIG. 1A above, heat energy from the device package 202 is transferred through the later of TIM 204, the metal plate 206, the layer of solder 212, and into the heat pipe 208, with each such interface in the heat energy transfer chain presenting thermal resistance.

As can be seen in FIG. 2, heat generated by the device package 202, represented by arrows 290 causes a working fluid in the heat pipe 210 to be vaporized from within a wick material 242 and into the interior of the heat pipe 210 which comprises a heat pipe chamber 280. The vaporized working fluid, represented by the arrows 290 passes toward a cool end 246 of the heat pipe 210. At the cool end 246 of the heat pipe 210, the working fluid condenses and returns, via the wick material 242 to the end of the heat pipe 210 at which the device package 202 is affixed. The working fluid may be water, distilled water, water mixed with a surfactant, and/or water mixed with another fluid for improved viscosity management, Few examples of the wicking material include homogenous wicking media such as metal fibers (e.g. made out of metals such as copper, aluminum, nickel, stainless steel, titanium, metal alloys, etc.), porous metals (e.g., porous copper), wire meshes (e.g., core wires), fibrous or dendritic materials, glass fibers, woven cloths and/or composite wicking media. This return flow of the condensed working fluid is denoted by arrows 292 in FIG. 2. This cycle of vaporization and condensation provides cooling of the device package 202. To encourage effective cooling, the cool end 246 of the heat pipe 210 may be attached to a heat sink or similar, which is not shown in FIG. 2. In some embodiments, the heat pipe chamber 280 is vacuum sealed to extract better performance with vacuum pressure of about 0.05-0.5 Torr.

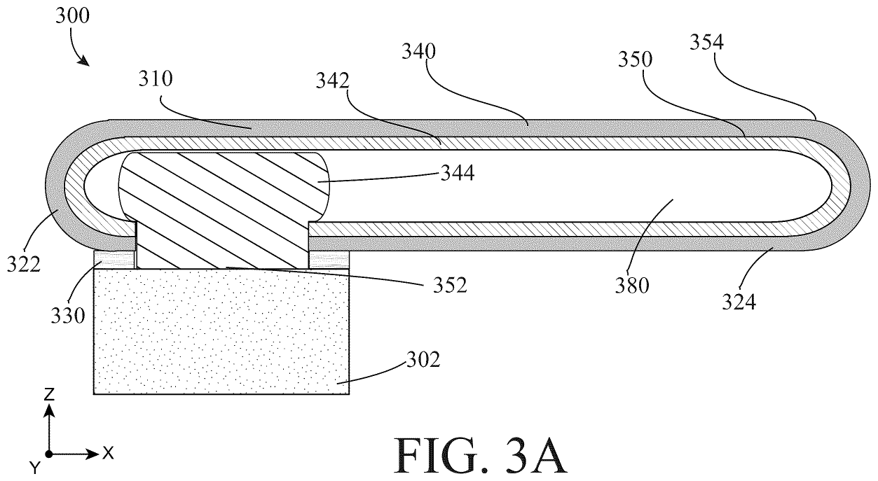

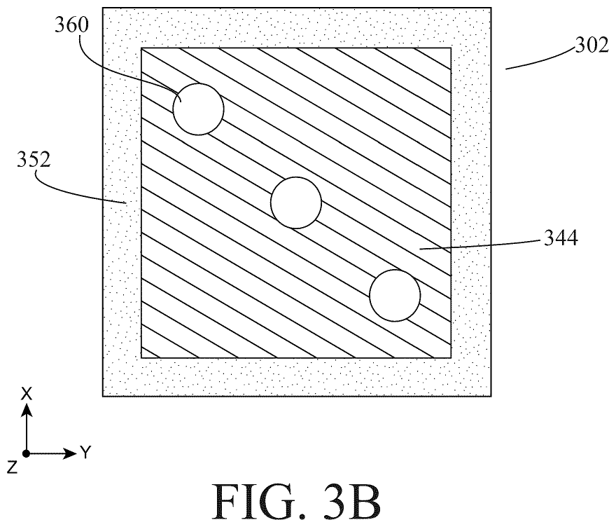

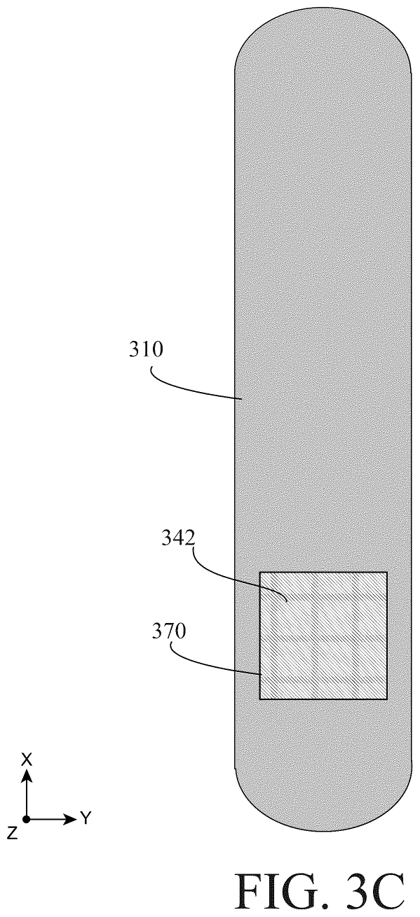

FIG. 3A shows a cooling arrangement 300 in which a device package 302 is in direct contact with a cooler. The cooler is a heat pipe 310. The heat pipe 310 is attached to the device package 302 with an adhesive 330. The adhesive 330 may be a compliant adhesive which may expand and contract, or may be flexible and move, such that when the heat pipe 310, which may be formed of copper, expands and contracts under heating and cooling. This may prevent damage to the device package 302 and may also prevent the heat pipe 310 from separating from the device package 302. The adhesive 330 may be such that it mitigates any mismatch in coefficient of thermal expansion between the device package 302 and the heat pipe 310. The adhesive 330 can also include solder. The heat pipe 310 may be affixed to the device package 302 by way of direct bonding or hybrid bonding as described later herein in place of adhesive 330.

The heat pipe 310 comprises a shell 340 which has an inner surface 350 and an outer surface 354. The shell 340 of the heat pipe 310 may be the outer wall of the heat pipe 310, and may be formed of a pipe or extrusion. In some examples, the outer wall of the heat pipe 310 may be formed of copper. In some examples the outer wall of the heat pipe 310 may be made of a metal or any other suitable material having a high thermal conductivity. The outer wall of the heat pipe 310 may form the shell 340 of the heat pipe 310 such that it forms the inner surface 350 of the heat pipe shell 340. The inner surface 350 of the shell 340 may therefore define a heat pipe chamber 380, and the inner surface 350 includes a wick material 342 thereupon. The wick material 342 may be affixed to the inside of the shell 340. The heat pipe 310 may be under partial or full vacuum conditions. Vacuum conditions may be taken as a condition well below normal atmospheric pressure, and may be created, for example, by removing air from a space, in this case the heat pipe chamber 380. The air may be removed, for example, by using a vacuum pump or similar. The wick material 342 may be made of a sintered metal powder, a mesh, a screen, fibrous or dendritic material, wires or wire mesh, and/or grooved wicks which have a series of grooves parallel to the pipe axis. The wick may also be facilitated by the roughening of the inner surface 350. The working fluid of the heat pipe 310 may be water, distilled water or any suitable working fluid.

Similarly to that shown in FIG. 2, the heat pipe 310 includes a device end 322 and a distal end 324, the distal end extending away from the device package 302.

The backside 352 of the device package 302 may, by way of attachment of the device package 302 with the heat pipe 310, form a portion of the shell 340 of the heat pipe such that the backside 352 of the device package 302 forms part of the inner surface 350 of the heat pipe. That is to say that the surface of the backside 352 of the device package 302 may become a part of the shell 340 of the heat pipe 310. In other words, the backside 352 of the device package 302 and the inner surface 350 of the heat pipe 310 may form a continuous surface, with the backside 352 of the device package 302 forming part of the shell 380 of the heat pipe 310. In some embodiments, the heat pipe 310 comprises an opening 370 (see FIG. 3C) disposed above the backside 352 of the device package 302 such that a portion of the backside 352 is exposed to the heat pipe chamber 380 (prior to the introduction of device wicking material 344, as discussed below) via the opening 370 in the heat pipe 310. Upon attachment of the heat pipe 310 to the device package 302, the portion of the backside 352 exposed to the heat pipe chamber 380, the adhesive 330, and the inner surface 350 of the shell 340 form the continuous surface. The opening 370 may be circular, oval, elliptical, hexagonal, square or rectangular shaped, or any other regular or irregular shape. Further, cross-sectional dimensions of the opening 370 in the X-Y plane may be less than a footprint of the device package in the X-Y plane, such that only the portion of the backside 352 of the package device 302 is exposed to the heat pipe chamber 380.

The backside 352 of the device package 302 may include a device wicking material 344 which may be a mesh, and, in particular, a copper mesh. This device wicking material 344 may be placed upon, adhered to, or affixed to, the portion of the backside 352 of the device package 302 that forms the portion of the shell 340. The device wicking material 344, in some examples, may not be affixed to the portion of backside 352 of the device package 302, instead simply being in contact therewith.

The device wicking material 344 may also be in contact with the wick material 342, such that the portion of the backside 352 of the device package 302 forms an integral part of the heat pipe 310. In this way, heat may be transferred directly from the device package 302 into the heat pipe 310, without the use of an intervening thermal interface material, to allow for effective cooling of the device package 302.

The device wicking material 344 may include holes therein to allow egress of vaporized working fluid within the heat pipe 310 into the interior portion of the heat pipe 310. In some cases, this working fluid may be water and the vaporized working fluid may be steam.

For example, the heat pipe 310 may include an opening of approximately 10 mm×10 mm, and the device wicking material 344 placed on the backside 352 of the device package 302 may also be approximately 10 mm×10 mm.

An example of device wicking material 344 is shown in FIG. 3B. The device wicking material 344 may include one or more holes 360 therein to allow the egress of steam in the case that the working fluid within the heat pipe 310 is water. For example, the device wicking material 344 may include holes 360 of approximately 0.5 mm, 1 mm or 5 mm in diameter or in the range between 0.5 mm to 10 mm, and these holes 360 may be in a repeating pattern. There may, for example, be one, two, or three holes 360 in the device wicking material 344. In some examples, more than three holes 360 may be present. In some examples as many as ten or twenty holes may be present.

Returning to FIG. 3A, a large quantity of device wicking material 344 may be placed on the backside 352 of the device package 302, such that the device wicking material 344 protrudes into the interior of the heat pipe 310. In the example shown in FIG. 3A, the device wicking material 344 reaches almost all of the way across the interior of the heat pipe 310 (i.e., from a lower surface to an upper surface). In some embodiments, the device wicking material 344 reaches half way or less than half way across the interior of the heat pipe 310. The device wicking material may also extend laterally in the X-axis direction (as shown) and/or the Y-axis direction beyond a sidewall of the opening.

FIG. 3C shows the heat pipe 310 having the opening 370 as described above cut therein, and in the example shown in FIG. 3C, the opening 370 is square. Through the opening 370, wick material 342 inside the heat pipe 310 can be seen.

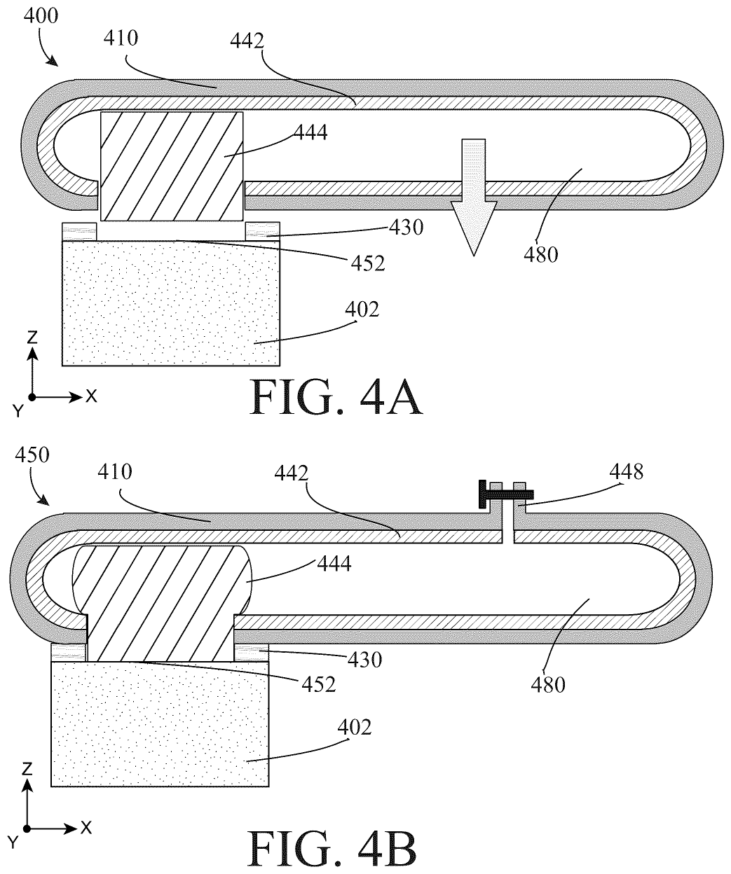

Turning now to FIG. 4A, a partially-assembled cooling arrangement 400 is shown. A device package 402 having a backside 452 is shown, along with a heat pipe 410. The heat pipe 410 includes a heat pipe chamber 480. The partially-assembled cooling arrangement 400 also includes with wick material 442 and device wicking material 444. An adhesive 430 is also shown which may, as described herein, be a compliant adhesive 430. As seen in FIG. 4A, the adhesive 430 is placed on the backside 452 of the device package 402 such that it is ready for the heat pipe 410 to be adhered to the device package 402. In this example, the device wicking material 444 is already placed within the heat pipe 410.

When the heat pipe 410 is moved toward the adhesive 430 and attached thereto such that the heat pipe 410 is attached to the backside 452 of the device package 402, the device wicking material 444 may make contact with the backside 452. Additionally, as described herein a portion of the backside 452 of the device package 402 may form part of an interior surface of the heat pipe 410. In some embodiments, the device wicking material 444 is placed on backside 452 of the device package 402.

An assembled cooling arrangement 450 is shown in FIG. 4B. This may exemplify an assembled version of the partially-assembled cooling arrangement 400 as shown in FIG. 4A. Like reference numbers are used, and as can be seen, the heat pipe 410 is adhered to the device package 402 by way of the adhesive 430. The device wicking material 444 is in contact with the backside 452 of the device package 402 and with the wick material 442 within the heat pipe 410. As seen in FIG. 4B, the device wicking material 444 may deform when the heat pipe 410 is affixed to the device package 402.

FIG. 4B also shows a sealable aperture 448 in the wall of the heat pipe 410. The sealable aperture 448 may, once the heat pipe 410 is attached to the device package 402, enable the interior of the heat pipe 410 to be evacuated such that the interior of the heat pipe 410 becomes at least a partial vacuum. In some cases, the heat pipe chamber 480 of the heat pipe 410 may be evacuated to become a substantially complete vacuum.

The sealable aperture 448 may also enable a working fluid may to be introduced into the heat pipe chamber 480 of the heat pipe 410. In an example the heat pipe 410 is formed of copper, and the working fluid may be water. The evacuation and introduction of working fluid into the heat pipe chamber 480 may be such that the heat pipe 410 becomes operational.

The heat pipe 410 may be attached to the device package 402 of FIG. 4B by way of direct bonding or hybrid bonding as described later herein in place of the adhesive 430.

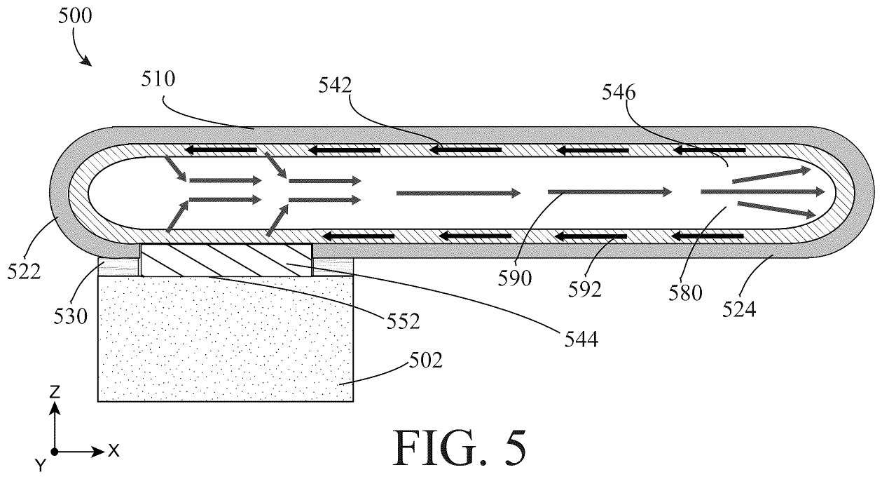

FIG. 5 shows a heat pipe cooling arrangement 500. A heat pipe 510 is affixed to a device package 502 as described herein. Similar to that which is described above herein the heat pipe 510 is affixed to the backside 552 of the device package 502 with an adhesive 530. The adhesive 530 may be compliant adhesive as described herein. Device wicking material 544 is placed against the backside of the chip 502 and is in contact with the wick material 542 within a heat pipe chamber 580 of the heat pipe 510. The heat pipe 510 in this example is made of copper, and the heat pipe chamber 580 is under at least a partial vacuum and contains water as a working fluid.

The heat pipe cooling arrangement 500 of FIG. 5 includes a device end 522 and a distal end 524, the distal end extending away from the device package 502.

As can be seen in FIG. 5, heat generated by the device package 502, represented by arrows 590 within the heat pipe chamber 580 causes the working fluid in the heat pipe 510 to be vaporized from within the wick material 542 and into the heat pipe chamber 580. The vaporized working fluid, represented by the arrows 590 passes toward a cool end 546 of the heat pipe 510. At the cool end 546 of the heat pipe 510, the working fluid condenses and returns, via the wick material 542 to the end of the heat pipe 510 at which the device package 502 is affixed. This return flow of the condensed working fluid is denoted by arrows 592 in FIG. 5. This cycle of vaporization and condensation provides cooling of the device package 502. To encourage effective cooling, the cool end 546 of the heat pipe, which is the distal end 524 of the heat pipe 510, may be attached to a heat sink or similar, which is not shown in FIG. 5.

In some examples, in place of the device wicking material 544, a dendritic copper material may be formed on the backside of the device package 502. This dendritic copper material may be a porous copper dendritic film. In some examples, copper or metallic dendrites may be grown on the backside of the device package at a wafer level. Such copper or metallic dendrites may be porous or rough, and may be porous copper or rough copper, and may be grown on the backside of the device package of the device package 502. In such examples, the adhesive 530 may be applied after the dendritic copper is grown or placed on the backside of the device package 502.

In some examples, an outer surface of the heat pipe includes a dielectric layer deposited thereupon (e.g., by patterning). As described herein, in some examples, the outer wall of the heat pipe 510 may be formed of copper, aluminum or stainless steel. In some examples, the outer wall of the heat pipe 510 may be made of a metal having a high thermal conductivity. The dielectric layer may be disposed on the outer surface of the heat pipe 510 such that the dielectric layer is between the outer surface of the heat pipe 510 and the backside 552 of the device package 502. This dielectric layer on the heat pipe 510 may enable the heat pipe 510 to be attached to the backside 552 of the device package 502 using direct dielectric bonds formed between the dielectric layer and the backside 552 of the device package 502. In some examples, the backside 552 of the device package 502 may include conductive features, and these conductive features may enable the heat pipe 510 to be attached to the backside 552 of the device package 502 by using hybrid bonds.

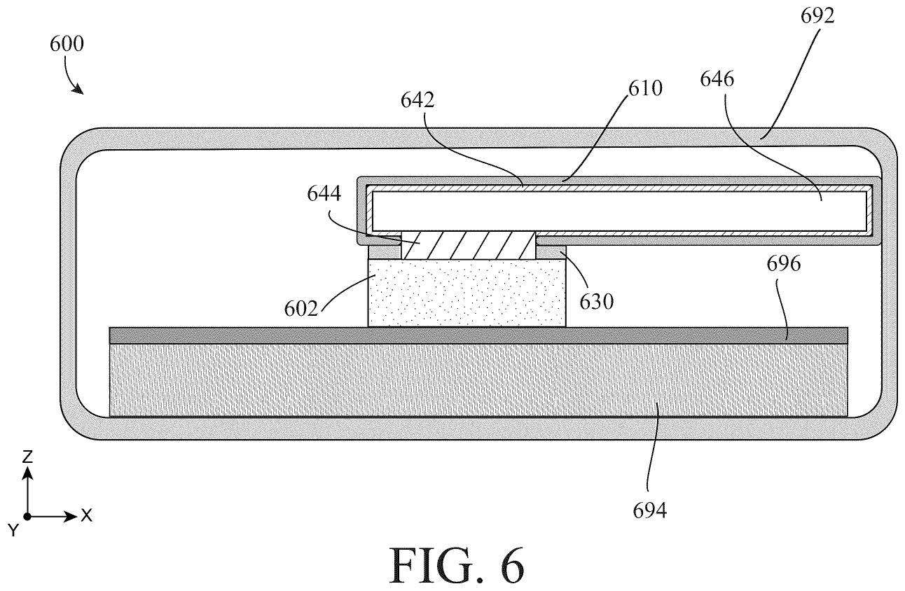

FIG. 6 shows a heat pipe cooling arrangement of the type described herein within the housing of an electronic device 600 (e.g., a desktop, a laptop, a tablets, a smartphone, etc.). The device 600 includes a casing 692, a display 694, a PCB 696, a device package 602, and a heat pipe 610.

The heat pipe 610 is attached to, and in thermal contact with the device package 602 as described herein. The heat pipe 610 is also in thermal contact with the casing 692 of the device 600 such that the casing 692 acts as a heat sink for dissipation of heat away from the device package 602, via the heat pipe 610. In some embodiments, the heat pipe 610 is also in thermal contact with the casing 692 via thermal pad, TIM, etc. In FIG. 6, an adhesive 630 is used to affix the heat pipe 610 to the device package 602. Device wicking material 644 and wick material 642 are present within the heat pipe 610. A cool end 646 of the heat pipe 610 is in contact with the casing 692 of the device 600, and this contact may be thermal contact to provide heat transfer from the device package 602, through the heat pipe 610, into the casing 692 of the device 600.

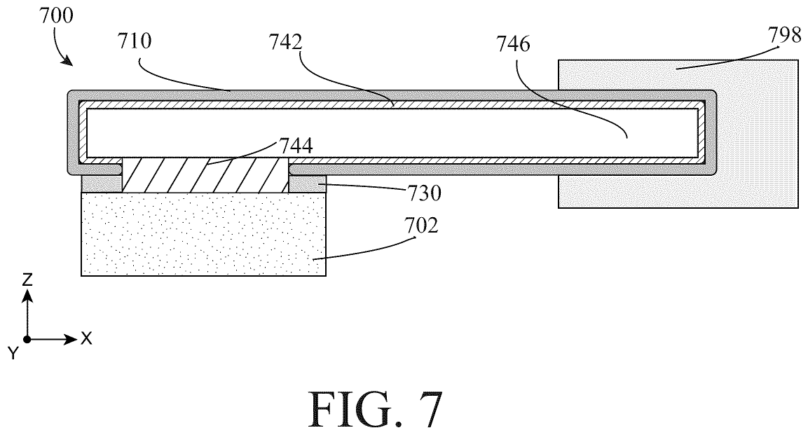

FIG. 7 shows a heat pipe cooling assembly 700 of the type described herein, with a heat pipe 710 in contact with a heat sink 798 (e.g., made from copper or aluminum). Cooling assembly 700 includes a device package 702, and the heat pipe 710.

The heat pipe 710 is attached to, and in thermal contact with the device package 702 as described herein. The heat pipe 710 is also in thermal contact with the heat sink 798 such that the heat sink 798 enables dissipation of heat away from the device package 702, via the heat pipe 710. In this example, an adhesive 730 is used to affix the heat pipe 710 to the device package 702. Device wicking material 744 and wick material 742 are present within the heat pipe 710. A cool end 746 of the heat pipe 710 is in contact with the heat sink 798, and this contact may be thermal contact to provide heat transfer from the device package 702, through the heat pipe 710, into the heat sink 798.

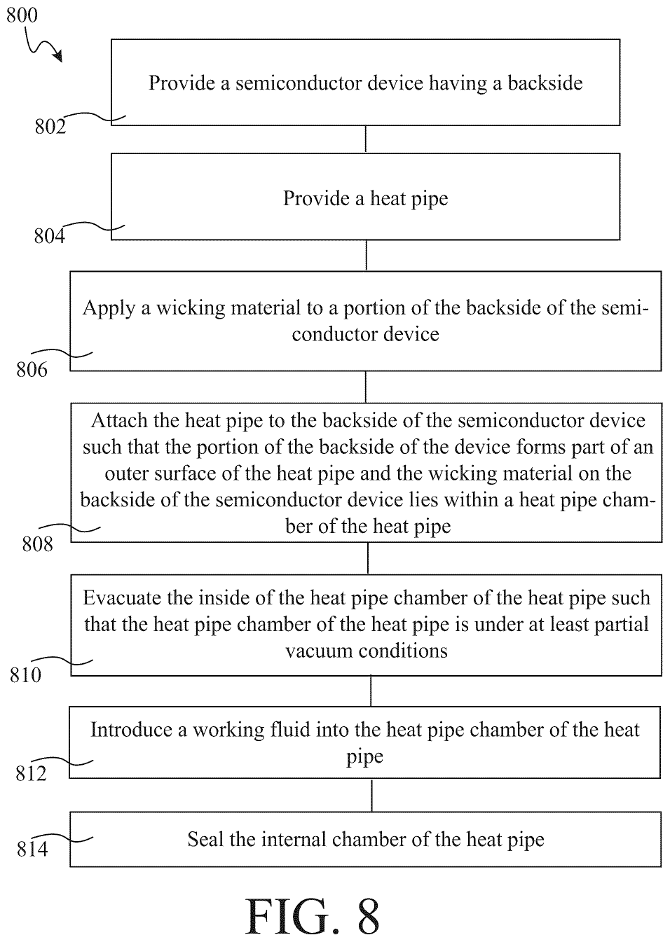

FIG. 8 shows a method 800 for assembly of a cooling assembly as described herein. At block 802, a semiconductor device or a device package 502 having a backside 552 as described herein is provided.

At block 804, a heat pipe (e.g., heat pipe 510) is provided. In some scenarios, the heat pipe 510 may be supplied with an opening or aperture ready to be installed onto the device package 502. In some scenarios, the heat pipe 510 may need to be modified to be installed on the device package 502. If the heat pipe 510 is to be modified to be installed on the device package 502, a hole may be made in the copper material of the heat pipe 510, but not through the wicking material 542 thereof.

At block 806, a device wicking material (e.g., device wicking material 544) is placed on the backside 552 of the device package 502. In some examples, a piece of the device wicking material 544 is cut and placed on the backside of the device package 502 which is substantially the same size as the hole in the heat pipe 510. In some examples, a dendritic copper material may be formed on the backside 552 of the device package 502. This dendritic copper material may be a porous copper dendritic film. In some examples, copper or metallic dendrites may be grown on the backside of the device package 502 at a wafer level. Such copper or metallic dendrites may be porous or rough, and may be porous copper or rough copper, and may be grown on the backside of the die of the device package 502.

At block 808, the heat pipe 510 is attached to the backside of the device package 502 such that the backside of the device forms part of an outer wall of the heat pipe 510 and the device wicking material 544 on the backside 552 of the device package 502 lies within an internal chamber 580 of the heat pipe 510. In some examples a compliant adhesive 530 as described herein may be applied to a perimeter of the backside 552 of the device package 502. The adhesive 530 may be applied using a jig, a former, or a template, or in some cases may be applied manually. In some examples, the adhesive 530 may be to another portion of the backside 552 of the device package 502 or the heat pipe 510, which may be a portion away from the device wicking material, and/or may be the perimeter of the backside 552 of the device package 502.

In some examples, if the adhesive 530 is not used, direct bonding may be used to attach the heat pipe 510 to the device package 502.

At block 810, the inside of the internal chamber 580 of the heat pipe 510 is at least partially evacuated to form at least a partial vacuum, i.e. such that the internal chamber 580 of the heat pipe 510 is under at least partial vacuum conditions.

At block 812 a working fluid or liquid introduced into the internal chamber 580 of the heat pipe 510.

At block 814, the internal chamber 580 of the heat pipe 510 is sealed.

The heat pipe 510 and the backside 552 of the device package 502 may be in direct contact. For example, in some embodiments, one or both of the heat pipe 510 and the backside 552 of the device package 502 may comprise a dielectric material layer, e.g., a first dielectric material layer and a second dielectric material layer respectively, and the heat pipe 510 is directly bonded to the backside 552 of the device package 502 through bonds formed between the dielectric material layers. In some embodiments, one of the heat pipe 510 or the backside 552 of the device package 502 may comprise a thin bonding dielectric layer (e.g. silicon nitride, etc.) and other element(s) may not include any such explicit bonding dielectric layer (or can have only native oxide layer). Here, the first and second dielectric material layers may be continuous layers, but it will be understood that one or both of the layers may not be continuous. For example, the first dielectric material layer may be disposed only on lower surfaces of the heat pipe 510 facing the backside 552 of the device package 502.

Beneficially, directly bonding the heat pipe 510 to the device package 502, as described above, reduces the thermal resistance therebetween and increases the efficiency of heat transfer from the device package 502 to the heat pipe 510.

In some embodiments, the heat pipe 510 may be attached to the device package 502 using a hybrid bonding technique, where bonds are formed between the dielectric material layers and between metal features, such as between first metal pads and second metal pads, disposed in the dielectric material layers.

Suitable dielectrics that may be used as the dielectric material layers include silicon oxides, silicon nitrides, silicon oxynitrides, silicon carbon nitrides, metal-oxides, metal-nitrides, silicon carbide, silicon oxycarbides, silicon oxycarbonitride, diamond-like carbon (DLC), or combinations thereof. In some embodiments, one or both of the dielectric material layers are formed of an inorganic dielectric material, e.g., a dielectric material substantially free of organic polymers. Typically, one or both of the dielectric layers are deposited to a thickness greater than the thickness of a native oxide, such as about 1 nanometer (nm) or more, 5 nm or more, 10 nm or more, 50 nm or more, or 100 nm or more. In some embodiments, one or both of the layers are deposited to a thickness of 3 micrometer or less, 1 micrometer or less, 500 nm or less, such as 100 nm or less, or 50 nm or less. The dielectric layer material and thickness may be optimized for lower thermal resistance between the device package 502 and the heat pipe 510.

If the heat pipe 510 is attached to the device package 502 by direct bonding, this may include forming dielectric layers on one or both the of the heat pipe 510 which may be a first substrate and the device package 502 which may be a second substrate, and directly bonding includes forming dielectric bonds between a first dielectric material layer of the first substrate and a second dielectric material layer of the second substrate (or forming dielectric bonds between one substrate and a dielectric material layer of the other substrate). Direct bonding processes join dielectric layers by forming strong chemical bonds (e.g., covalent bonds) between the dielectric layers.

Generally, directly bonding the surfaces (of the dielectric material layers formed on the first and second substrates) includes preparing, aligning, and contacting the surfaces. Examples of dielectric material layers include silicon oxide, silicon nitride, silicon oxynitride, and silicon carbonitride. Preparing the surfaces may include smoothing the respective surfaces to a desired surface roughness, such as between 0.1 to 3.0 nm RMS, activating the surfaces to weaken or open chemical bonds in the dielectric material, and terminating the surfaces with a desired species. Smoothing the surfaces may include polishing the first and second substrates using a CMP process. Activating and terminating the surfaces with a desired species may include exposing the surfaces to radical species formed in a plasma. The bond interface between the bonded dielectric layers can include a higher concentration of materials from the activation and/or last chemical treatment processes compared to the bulk of the bonding layers. For example, some embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen concentration peak can be formed at the bond interface between non-conductive bonding surfaces.

In some embodiments, the plasma is formed using a nitrogen-containing gas, e.g., N2, and the terminating species includes nitrogen, or nitrogen and hydrogen. In some embodiments, fluorine may also be present within the plasma. In some embodiments, the surfaces may be activated using a wet cleaning process, e.g., by exposing the surfaces to an aqueous ammonia solution. In some embodiments, the dielectric bonds may be formed using a dielectric material layer deposited on only one of the first and second substrates, but not on both. In those embodiments, the direct dielectric bonds may be formed by contacting the deposited dielectric material layer of one of the first and second substrates directly with a bulk material surface (or such a surface with a native oxide) of the other substrate.

Directly forming direct dielectric bonds between the first and second substrates may include bringing the prepared and aligned surfaces into direct contact at a temperature less than 150° C., such as less than 100° C., for example, less than 30° C., or about room temperature, e.g., between 20° C. and 30° C. Without intending to be bound by theory, in the case of directly bonding surfaces terminated with nitrogen and hydrogen (e.g., NH2 groups), it is believed that the hydrogen terminating species diffuse from the interfacial bonding surfaces, and chemical bonds are formed between the remaining nitrogen species during the direct bonding process. In some embodiments, the direct bond is strengthened using an anneal process, where the substrates are heated to and maintained at a temperature of greater than about 30° C. and less than about 450° C., for example, greater than about 50° C. and less than about 250° C., or about 150° C. for a duration of about 5 minutes or more, such as about 15 minutes. Typically, the bonds will strengthen over time even without the application of heat. Thus, in some embodiments, the method does not include heating the substrates.

In embodiments where the first and second substrates are bonded using hybrid dielectric and metal bonds, a method may further include planarizing or recessing the metal features below the dielectric field surface before contacting and bonding the dielectric material layers. After the dielectric bonds are formed, the first and second substrates may be heated to a temperature of 150° C. or more and maintained at the elevated temperature for a duration of about 1 hour or more, such as between 8 and 24 hours, to form direct metallurgical bonds between the metal features.

Suitable direct dielectric and hybrid bonding technologies that may be used to perform aspects of the methods described herein include ZiBond® and DBIR, each of which are commercially available from Adeia Holding Corp., San Jose, CA, USA.

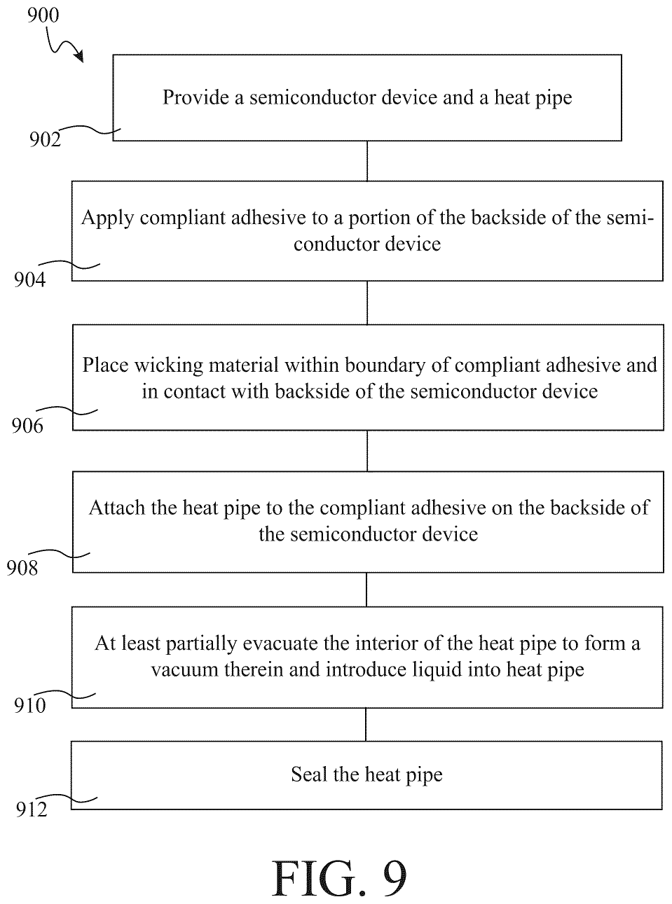

FIG. 9 shows a method 900 for assembly of a cooling assembly as described herein. At block 902, a semiconductor device (e.g., semiconductor device 502) as described herein is provided, along with a heat pipe (e.g., heat pipe 510). In some scenarios, the heat pipe 510 may be supplied with an opening or aperture ready to be installed onto the device package 502. In some scenarios, the heat pipe 510 may need to be modified to be installed on the semiconductor device 502. If the heat pipe 510 is to be modified to be installed on the semiconductor device 502, a hole may be made in the copper material of the heat pipe 510, but not through a wicking material (e.g., wicking material 542) thereof.

At block 904, a compliant adhesive 530 as described herein may be applied to the perimeter of the backside 552 of the semiconductor device 502. The adhesive 530 may be applied using a jig, former, or template, or in some cases may be applied manually. In some examples, if the adhesive 530 is not used, direct bonding may be used to attach the heat pipe 510 to the semiconductor device 502.

At block 906, the wicking material 544 is placed within the perimeter of the adhesive 530. In some examples, a piece of the wicking material 544 is cut and placed on the backside of the semiconductor device 502 which is substantially the same size as the hole in the heat pipe 510. In some examples, a dendritic copper material may be formed on the backside of the semiconductor device 502. This dendritic copper material may be a porous copper dendritic film. In some examples, copper or metallic dendrites may be grown on the backside 552 of the semiconductor device 502 at a wafer level. Such copper or metallic dendrites may be porous or rough, and may be porous copper or rough copper, and may be grown on the backside of the die of the semiconductor device 502. In such examples, the adhesive 530 may be applied after the dendritic copper is grown or placed on the backside of the semiconductor device 502.

At block 908, the heat pipe 510 is affixed to the adhesive 530 and therefore to the backside 552 of the semiconductor device 502. In this way, the wicking material 544 is within the heat pipe 510 and the surface of the backside 552 of the semiconductor device 502 forms a wall of the heat pipe 510.

At block 910, the heat pipe 510 may be at least partially evacuated to form at least a partial vacuum, and a working fluid or liquid introduced into the interior of the heat pipe 510.

At block 912, the heat pipe 510 is sealed.

The embodiments discussed above are intended to be illustrative and not limiting. One skilled in the art would appreciate that individual aspects of the cooling assemblies, device packages, and methods discussed herein may be omitted, modified, combined, and/or rearranged without departing from the scope of the disclosure.

1. An integrated cooling assembly comprising:
a semiconductor device; and
a heat pipe attached to a backside of the semiconductor device, wherein:
the heat pipe comprises a shell which defines a heat pipe chamber, the shell having an inner surface and an outer surface;
the inner surface of the heat pipe chamber includes a wick material thereupon; and
the backside of the semiconductor device is in contact with the wick material.

2. The integrated cooling assembly of claim 1, wherein the backside of the semiconductor device forms a portion of the shell of the heat pipe such that the backside of the semiconductor device forms a portion of the inner surface of the heat pipe chamber.

3. The integrated cooling assembly of claim 1, wherein the heat pipe is attached to the backside of the semiconductor device with an adhesive.

4. The integrated cooling assembly of claim 3, wherein the adhesive is a compliant adhesive.

5. The integrated cooling assembly of claim 1, wherein the heat pipe is attached to the backside of the semiconductor device with solder.

6. The integrated cooling assembly of claim 1, wherein a portion of the outer surface of the heat pipe includes a dielectric layer deposited thereupon.

7. The integrated cooling assembly of claim 6, wherein the dielectric layer is disposed between the portion of the outer surface of the heat pipe and the backside of the semiconductor device.

8. The integrated cooling assembly of claim 7, wherein the heat pipe is attached to the backside of the semiconductor device using direct dielectric bonds formed between the dielectric layer and the backside of the semiconductor device.

9. The integrated cooling assembly of claim 6, wherein the backside of the semiconductor device further includes conductive features thereupon.

10. The integrated cooling assembly of claim 9, wherein the heat pipe is attached to the backside of the semiconductor device using hybrid bonds.

11. The integrated cooling assembly of claim 1, wherein the wick material is a mesh, a sintered powder deposited on the inner surface of the heat pipe chamber, a braid, or grooves formed on the inner surface of the heat pipe chamber.

12-16. (canceled)

17. The integrated cooling assembly of claim 11, wherein the wick material extends across the portion of the backside of the semiconductor device that forms the portion of the shell.

18-22. (canceled)

23. The integrated cooling assembly of claim 1, wherein the heat pipe has a proximal end and a distal end, and the proximal end of the heat pipe is attached to the backside of the semiconductor device.

24-27. (canceled)

28. A method of manufacturing an integrated cooling assembly, the method comprising:
providing a semiconductor device having a backside;
providing a heat pipe;
applying a wicking material to a portion of the backside of the semiconductor device;
attaching the heat pipe to the backside of the semiconductor device such that the portion of the backside of the semiconductor device forms part of an outer surface of the heat pipe and the wicking material on the backside of the semiconductor device lies within a heat pipe chamber of the heat pipe;
evacuating the inside of the heat pipe chamber of the heat pipe such that the heat pipe chamber of the heat pipe is under at least partial vacuum conditions;
introducing a working fluid into the heat pipe chamber of the heat pipe; and
sealing the heat pipe chamber of the heat pipe.

29. The method of claim 28, wherein attaching the heat pipe to the backside of the semiconductor device comprises:
applying an adhesive to another portion of the backside of the semiconductor device or the heat pipe; and
attaching the heat pipe to the another portion of the backside of the semiconductor device using the adhesive.

30. The method of claim 29, wherein applying the adhesive to the another portion of the backside of the semiconductor device or the heat pipe comprises applying a compliant adhesive to the backside of the semiconductor device or the heat pipe.

31. The method of claim 28, wherein attaching the heat pipe to the backside of the semiconductor device comprises:
attaching the heat pipe to the backside of the semiconductor device with solder.

32. The method of claim 28, further comprising:
depositing a dielectric layer on a portion of the outer surface of the heat pipe.

33. The method of claim 32, wherein attaching the heat pipe to the backside of the semiconductor device comprises:
directly bonding the backside of the semiconductor device to the heat pipe to form direct bonds between the dielectric layer on the heat pipe and the backside of the semiconductor device.

34. The method of claim 28, further comprising:
forming conductive features on the backside of the semiconductor device, wherein attaching the heat pipe to the backside of the semiconductor device comprises:
attaching the backside of the semiconductor device to the heat pipe using hybrid bonds.

35-39. (canceled)
